(19) United States
(12) Patent Application Publication
(10) Pub. No.: US 2016/0172207 A1
(43) Pub. Date: Jun. 16, 2016

(54) PELLICLE MEMBRANE AND METHOD OF MANUFACTURING THE SAME

(71) Applicant: Samsung Electronics Co., Ltd., Suwon-si (KR)

(72) Inventors: Sungwon KWON, Suwon-si (KR); Chalykh ROMAN, Suwon-si (KR)

(21) Appl. No.: 14/955,455

(22) Filed: Dec. 1, 2015

(30) Foreign Application Priority Data
Dec. 10, 2014 (KR) 10-2014-0177559

(51) Int. Cl. H01L 21/308; H01L 21/306; H01L 21/3065; H01L 21/02

(52) U.S. Cl. CPC H01L 21/3088; H01L 21/02532; H01L 21/02609; H01L 21/30604; H01L 21/3065; H01L 21/3081; H01L 21/3085; H01L 21/3086

(57) ABSTRACT

A method of manufacturing a pellicle membrane includes forming a silicon layer on a substrate, forming a mask pattern on the silicon layer, and performing a wet etching process on the silicon layer exposed by the mask pattern to form silicon patterns with an uneven structure. A contact area between the silicon patterns and the substrate may be larger than that between the silicon patterns and the mask pattern, and each of the silicon patterns may be formed in such a way that a side surface thereof has an ascending slope in a vertical direction oriented from the substrate toward the mask pattern and is a crystal plane of (111).

### CROSS-REFERENCE TO RELATED APPLICATIONS

This U.S. non-provisional patent application claims priority under 35 U.S.C. §119 to Korean Patent Application No. 10-2014-0177559, filed on Dec. 10, 2014, in the Korean Intellectual Property Office, the entire contents of which are hereby incorporated by reference in its entirety.

### BACKGROUND OF THE INVENTION

Example embodiments of inventive concepts relate to a pellicle membrane and a method of manufacturing the same, and in particular, to a pellicle membrane with a convex and/or concave structure and/or a method of manufacturing the same.

A semiconductor device may include fine patterns formed using a photoresist pattern. The photoresist pattern may be formed using a photomask with a pellicle. The pellicle may be attached on the photomask to protect the photomask against particles or an external damage.

### SUMMARY

Example embodiments of inventive concepts provide a pellicle membrane with a convex-concave or uneven structure and a method of manufacturing the same.

According to some example embodiments of inventive concepts, a method of manufacturing a pellicle membrane may include forming a silicon layer on a substrate, forming a mask pattern on the silicon layer, and performing a wet etching process on the silicon layer exposed by the mask pattern to form silicon patterns with an uneven structure. A contact area between the silicon patterns and the substrate may be larger than that between the silicon patterns and the mask pattern, and each of the silicon patterns may be formed in such a way that a side surface thereof has an ascending slope in a vertical direction oriented from the substrate toward the mask pattern and is a crystal plane of (111).

In at least one example embodiment, the mask pattern may include a hard mask pattern, and a resist pattern provided on the hard mask pattern.

In at least one example embodiment, the wet etching process may be performed using etching solution containing at least one of ethylenediamine pyrocatechol (EDP), potassium hydroxide (KOH), isopropyl alcohol (IPA), or tetramethylammonium hydroxide (TMAH).

In at least one example embodiment, if the etching solution is EDP, the hard mask pattern includes at least one of silicon dioxide (SiO₂), silicon nitride (Si₃N₄), gold (Au), chromium (Cr), or silver (Ag).

In at least one example embodiment, if the etching solution is KOH, IPA, or TMAH, the hard mask pattern includes one of silicon dioxide (SiO₂) or silicon nitride (Si₃N₄).

In at least one example embodiment, the mask pattern may be formed to have openings exposing the silicon layer, and the openings may be arranged in a regular manner, along a first direction and a second direction crossing the first direction.

In at least one example embodiment, the mask pattern may be formed to have an island shape.

In at least one example embodiment, the silicon patterns may be arranged at a uniform interval.

In at least one example embodiment, the silicon pattern may be formed to have top and side surfaces meeting at an obtuse angle.

In at least one example embodiment, the method may further include removing the mask pattern, after the wet etching process.

According to example embodiments of inventive concepts, a method of manufacturing a pellicle membrane may include forming a silicon layer on a substrate, forming a first resist pattern on the silicon layer, patterning the first resist pattern and the silicon layer exposed by the first resist pattern using a dry etching process to form a second resist pattern and silicon patterns. The second resist pattern may be formed to have a width and a thickness smaller than those of the first resist pattern, the silicon patterns may be formed to provide an uneven structure on the silicon layer, and a contact area between the silicon patterns and the substrate may be larger than that between the silicon patterns and the second resist pattern.

In at least one example embodiment, the silicon pattern may be formed to have top and side surfaces meeting at an obtuse angle.

In at least one example embodiment, the dry etching process may be performed using an etching gas containing fluorine.

In at least one example embodiment, the silicon patterns may be formed at a uniform interval on the silicon layer and each of the silicon patterns may be shaped like a bar.

In at least one example embodiment, the method may further include removing the second resist pattern.

According to some example embodiments of inventive concepts, a pellicle membrane may include a silicon layer and silicon patterns provided on the silicon layer. Each of the silicon patterns may be provided in such a way that a side surface thereof has an ascending slope in a direction away from the silicon layer and is a crystal plane of (111).

In at least one example embodiment, each of the silicon patterns may have a vertical section shaped like a trapezoid, a triangle, or a semi-circle.

In at least one example embodiment, each of the silicon patterns may be shaped like a pyramid, a cone, or a polypyramid.

In at least one example embodiment, the silicon patterns may be arranged at a uniform interval.

In at least one example embodiment, the pellicle membrane may further include a capping layer provided on a bottom surface of the silicon layer to face the silicon patterns.

In some example embodiments, a method of manufacturing a pellicle membrane is provided. The method includes forming a silicon layer on a substrate and forming silicon patterns on the silicon layer. Each of the silicon patterns is formed such that a side surface thereof has an ascending slope in a vertical direction oriented from the substrate.

In some example embodiments, the forming a silicon layer on a substrate includes sequentially stacking a silicon layer and a hard mask layer on a substrate. In at least one example embodiment, the forming silicon patterns includes forming a photoresist on the hard mask layer so as to define openings exposing the hard mask layer, the openings being regularly arranged in a first direction and a second direction, patterning the hard mask layer to form a hard mask pattern, and forming silicon patterns on the silicon layer using the hard mask pattern as a mask. The silicon patterns are arranged at substantially uniform intervals. A contact area between the silicon patterns and the substrate is larger than that between the silicon patterns and the hard mask pattern. The silicon patterns have a concave shape and a side surface of the silicon patterns is rounded.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1 is a schematic diagram illustrating an example embodiment of a substrate processing system.

FIG. 2 is a schematic diagram illustrating an example embodiment of an exposure apparatus of FIG. 1.

FIG. 3 is a plan view illustrating a pellicle membrane according to at least one example embodiments.

FIG. 4 is a sectional view taken along line I-I′ of FIG. 3 to illustrate pellicle membrane according to an example embodiment.

FIG. 5 is a sectional view taken along line I-I′ of FIG. 3 to illustrate pellicle membrane according to other example embodiments.

FIGS. 6A through 6D are sectional views illustrating a method of forming a pellicle membrane according to example embodiments.

FIGS. 7A through 7D are sectional views illustrating a method of forming a pellicle membrane according to other example embodiments.

FIGS. 8A through 8C are sectional views illustrating a method of forming a pellicle membrane according to still other example embodiments.

FIGS. 9A through 9C are sectional views illustrating a method of forming a pellicle membrane according to some example embodiments.

FIG. 10 is a graph showing reflectance characteristics of a pellicle membrane according to some example embodiments.

FIG. 11 is a diagram exemplarily illustrating a lithography process of exposing a substrate using a mask.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which some example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

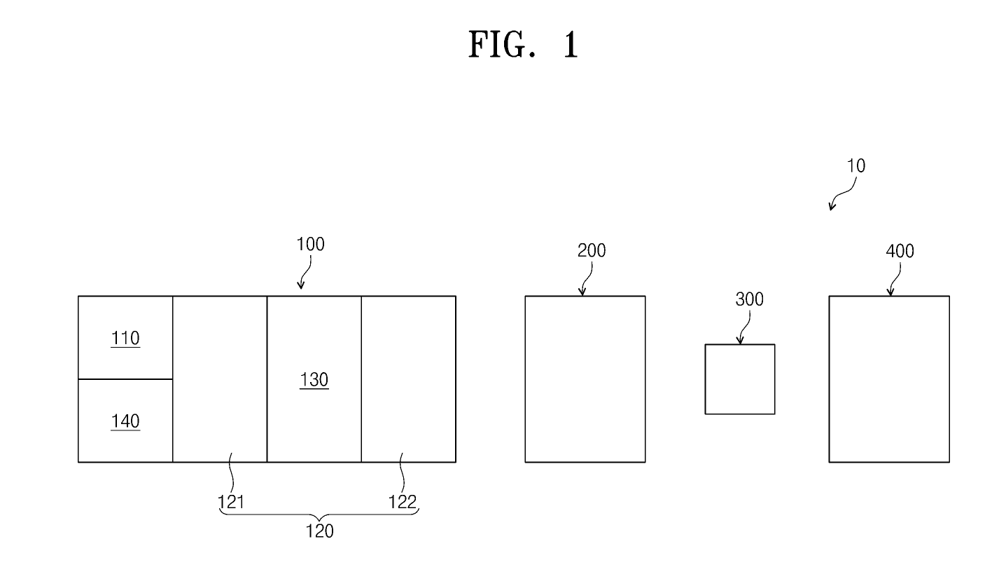

FIG. 1 is a schematic diagram illustrating some example embodiments of a substrate processing system.

Referring to FIG. 1, a substrate processing system 10 may be a lithography system. For example, the substrate processing system 10 may be used to form photoresist patterns on a substrate. In some example embodiments, the substrate processing system 10 may include a spin-coating unit 100, an exposure apparatus 200, a mask transfer unit 300, and a pellicle repair unit 400.

The spin-coating unit 100 may be configured to perform a photoresist coating process, a bake process, a post-exposure bake process, and a developing process. In some example embodiments, the spin-coating unit 100 may include a spin coater 110, substrate transfer parts 120, a baker 130, and a developer 140. The spin coater 110 may be configured to coat a photoresist layer on a substrate. The substrate transfer parts 120 may be used to move a substrate in the spin-coating unit 100. The substrate transfer parts 120 may include a first substrate transfer part 121 and a second substrate transfer part 122. The first substrate transfer part 121 may be used to change a position of a substrate, for example, between the spin coater 110 and the baker 130 and/or between the developer 140 and the baker 130. The baker 130 may be used to perform a bake process and a post-exposure bake process. A photoresist layer may be cured in the baker 130. The second substrate transfer part 122 may be used to move a substrate between the baker 130 and the exposure apparatus 200.

The exposure apparatus 200 may be configured to perform an exposure process. In some example embodiments, the exposure apparatus 200 may include an extreme ultraviolet (EUV) exposure system. The mask transfer unit 300 may be disposed between the exposure apparatus 200 and the pellicle repair unit 400. The mask transfer unit 300 may be configured to move a mask between the exposure apparatus 200 and the pellicle repair unit 400. The pellicle repair unit 400 may be configured to repair a pellicle, when the pellicle is contaminated. If the pellicle is repaired, it may be moved to the exposure apparatus 200 by the mask transfer unit 300.

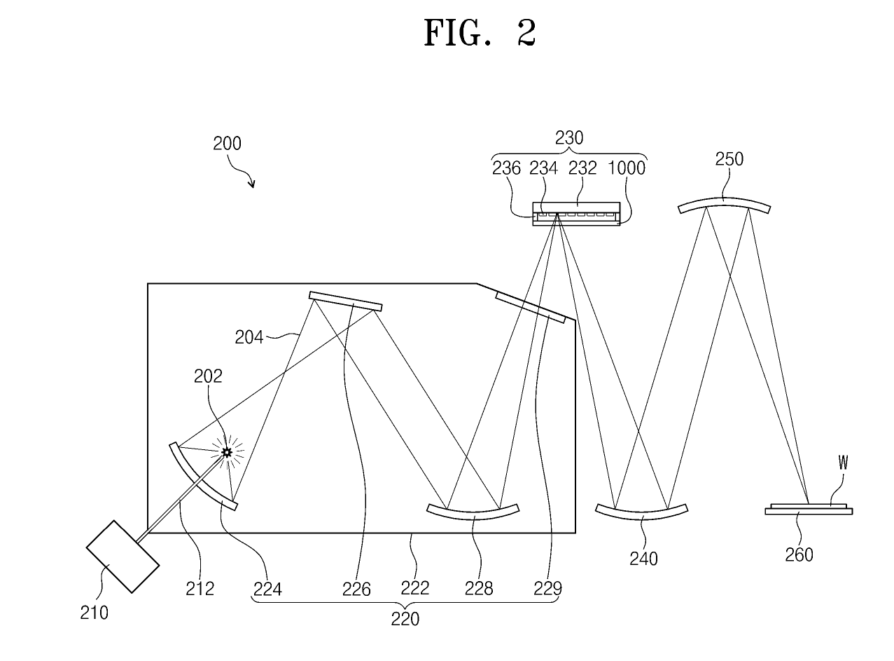

FIG. 2 is a schematic diagram illustrating an example of the exposure apparatus 200 of FIG. 1. The exposure apparatus 200 may include an EUV exposure system. The exposure apparatus 200 may include an EUV source 202, a pumping light source 210, an illumination part 220, a mask 230, projection parts 240 and 250, and a stage 260, on which a substrate W is loaded.

The EUV source 202 may be provided in the illumination part 220. The EUV source 202 may be excited by a laser beam 212 to generate an EUV beam 204. In some example embodiments, the EUV source 202 may include at least one of tin (Sn), xenon (Xe), titanium (Ti), or lithium (Li), which may be in a plasma state. The EUV source 202 of tin may generate the EUV beam 204 having a wavelength of about 13.5 nm.

The pumping light source 210 may include a laser-beam generating device. The pumping light source 210 may be configured to provide the laser beam 212 to the illumination part 220. The laser beam 212 may be a pump light to be provided to the EUV source 202. The laser beam 212 may be a monochromatic light having a wavelength ranging from about 400 nm to 800 nm.

The illumination part 220 may be configured to provide the EUV beam 204 to the mask 230. In some example embodiments, the illumination part 220 may include a source housing 222, a collector mirror 224, a field facet mirror 226, a pupil facet mirror 228, and a source blocking part 229.

The source housing 222 may be configured to enclose the collector mirror 224, the field facet mirror 226, the pupil facet mirror 228, and the source blocking part 229. The EUV source 202 may be provided in the source housing 222. For example, the EUV source 202 may be disposed between the collector mirror 224 and the source blocking part 229. The pumping light source 210 may be configured to provide the laser beam 212 from the outside to the inside of the source housing 222.

The collector mirror 224 may be configured to reflect the EUV beam 204 generated by the EUV source 202 toward the field facet mirror 226. The EUV beam 204 may be focused on the field facet mirror 226. The collector mirror 224 may be configured in such a way that the laser beam 212 propagates through a center of the collector mirror 224.

The field facet mirror 226 may be configured to reflect the EUV beam 204 toward the pupil facet mirror 228. The field facet mirror 226 may include a flat mirror.

The pupil facet mirror 228 may focus the EUV beam 204 on the mask 230. The mask 230 may be provided outside the source housing 222. The pupil facet mirror 228 may include a concave mirror.

The source blocking part 229 may be provided in the source housing 222 positioned between the pupil facet mirror 228 and the mask 230. The EUV beam 204 may propagate through the source blocking part 229. For example, the EUV beam 204 may be transmitted from the inside of the source housing 222 to the outside. The source blocking part 229 may be configured to block a fraction of the EUV source 202. The EUV source 202 may be moved from the collector mirror 224 to the source blocking part 229 along the EUV beam 204. The source blocking part 229 may include a membrane, whose thickness is of the order of nanometer. For example, the source blocking part 229 may include graphene. However, in certain cases, the EUV source 202 may be leaked from the source housing 222. For example, if the membrane is broken, the EUV source 202 may pass through the source blocking part 229. Alternatively, the EUV source 202 may be leaked to the neighborhood of the membrane.

The mask 230 may be configured to reflect the EUV beam 204 toward projection parts 240 and 250. In some example embodiments, the mask 230 may include a mask substrate 232, mask patterns 234, frames 236, and a pellicle membrane 1000. The mask substrate 232 may reflect the EUV beam 204. The mask substrate 232 may include a reflection layer (not shown), which contains molybdenum (Mo) and silicon (Si). The mask patterns 234 may be provided on the mask substrate 232. Shapes and disposition of the mask patterns 234 may be transferred onto the substrate W. The mask patterns 234 may absorb the EUV beam 204. Alternatively, the mask substrate 232 may absorb the EUV beam 204, and the mask patterns 234 may reflect the EUV beam 204. The frames 236 may be provided on an edge of the mask substrate 232 around the mask patterns 234. The pellicle membrane 1000 may be provided on the frames 236. The pellicle membrane 1000 may be provided to cover the mask patterns 234 and the mask substrate 232.

The pellicle membrane 1000 may be configured to allow the EUV beam 204 to pass therethrough. In some example embodiments, the pellicle membrane 1000 may have a thickness of nanometer order. The pellicle membrane 1000 may protect the top surface of the mask substrate 232 and the mask patterns 234 against pollutants (e.g., particles). The pollutants may be formed on the pellicle membrane 1000. Most of the pollutants may be the EUV source 202. Most of the pollutants may have, for example, a diameter ranging from about 0.1 μm to about 1 μm.

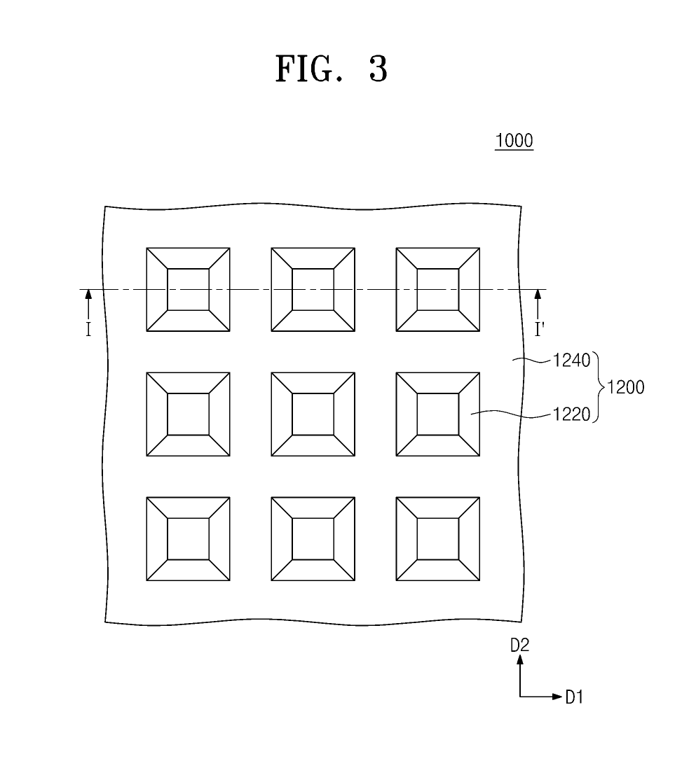

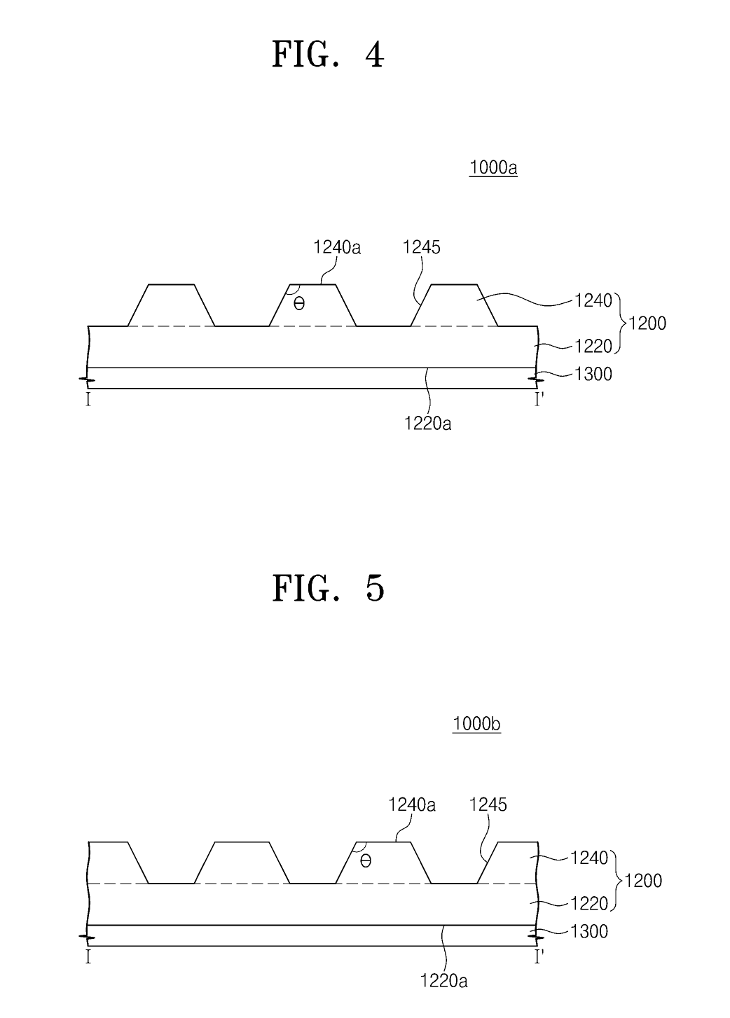

FIG. 3 is a plan view illustrating a pellicle membrane according to at least one example embodiment. FIG. 4 is a sectional view taken along line I-I′ of FIG. 3 to illustrate pellicle membrane according to some example embodiments, and FIG. 5 is a sectional view taken along line I-I′ of FIG. 3 to illustrate pellicle membrane according to other example embodiments.

Referring to FIGS. 3 through 5, a pellicle membrane 1000 may include a silicon layer 1220 and silicon patterns 1240. The silicon layer 1220 and the silicon patterns 1240 may include at least one of silicon dioxide (SiO₂), silicon nitride (Si₃N₄), and/or silicon compounds containing zirconium (Zr), molybdenum (Mo), and ruthenium (Ru). The silicon patterns 1240 may be provided on the silicon layer 1220. The silicon patterns 1240 may be arranged spaced apart from each other by a specific space, thereby forming an uneven structure. A distance between the silicon patterns may be similar to the thickness of the silicon layer. For example, each of the silicon patterns 1240 may have a convex shape, as shown in FIG. 4, and/or a concave shape, as shown in FIG. 5. Each of the silicon patterns 1240 may have a vertical section shaped like a trapezoid. The silicon patterns 1240 may be arranged with a uniform space. As another example, each of the silicon patterns 1240 may have a vertical section shaped like a triangle or a semi-circle. The silicon patterns 1240 may have a side surface, which is at an angle to a top surface of the silicon layer 1220. For example, the side surface of the silicon patterns 1240 may be formed to have an ascending slope in a direction oriented from the silicon layer 1220 to the silicon patterns 1240. Each of the silicon patterns 1240 may be shaped like a pyramid, a cone, a sphere, or a polypyramid. A side surface 1245 of the silicon patterns 1240 may be a crystal plane of (111). Each of the silicon patterns 1240 may be formed in such a way that top and side surfaces 1240a and 1240 meet each other at obtuse angle θ. The silicon patterns 1240 may be regularly arranged along two non-parallel directions (e.g., a first direction D1 and a second direction D2).

A bottom surface 1220a of the silicon layer 1220 may be flat. A capping layer 1300 may be provided on the bottom surface 1220a of the silicon layer 1220. In certain embodiments, the capping layer 1300 may be a silicon nitride layer.

In the case where an ultraviolet light is reflected by the mask 230 of FIG. 2 and is incident into the substrate W, some of patterns on the substrate W may be formed to have an abnormal profile. According to some example embodiments, ultraviolet light having a wavelength of 100 nm to 400 nm may be scattered by the silicon patterns 1240 arranged with the specific or uniform space. The scattering may reduce an amount of the ultraviolet light to be reflected by the pellicle membrane 1000a or 1000b, which makes it possible to form fine patterns on the substrate W using EUV light reflected by the mask 230 of FIG. 2.

Further, since the silicon patterns 1240 are spaced apart from each other with a nanometer-scale interval, it is possible to prevent or reduce pollutants from being attached to the pellicle membrane 1000a or 1000b. Even if pollutants are attached to the pellicle membrane 1000a or 1000b, an empty space may be formed between the silicon patterns 1240 and the pollutants, due to the uneven profile of the silicon patterns 1240. In this case, the pollutants can be easily removed from the pellicle membrane 1000a and 1000b, using, for example, an air brushing method of injecting the air into the empty space.

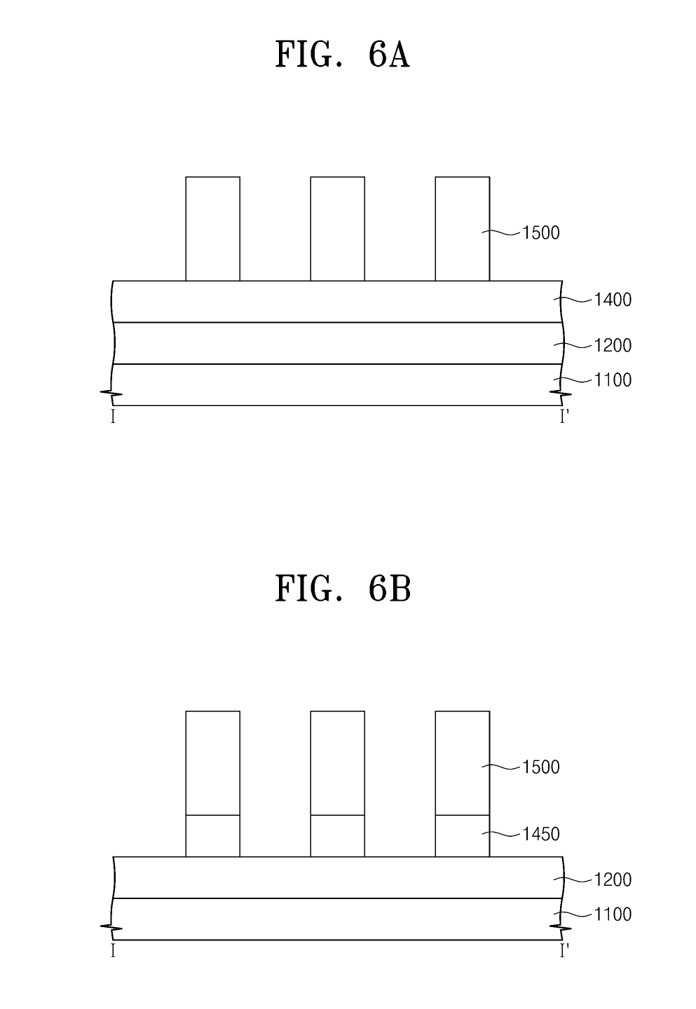

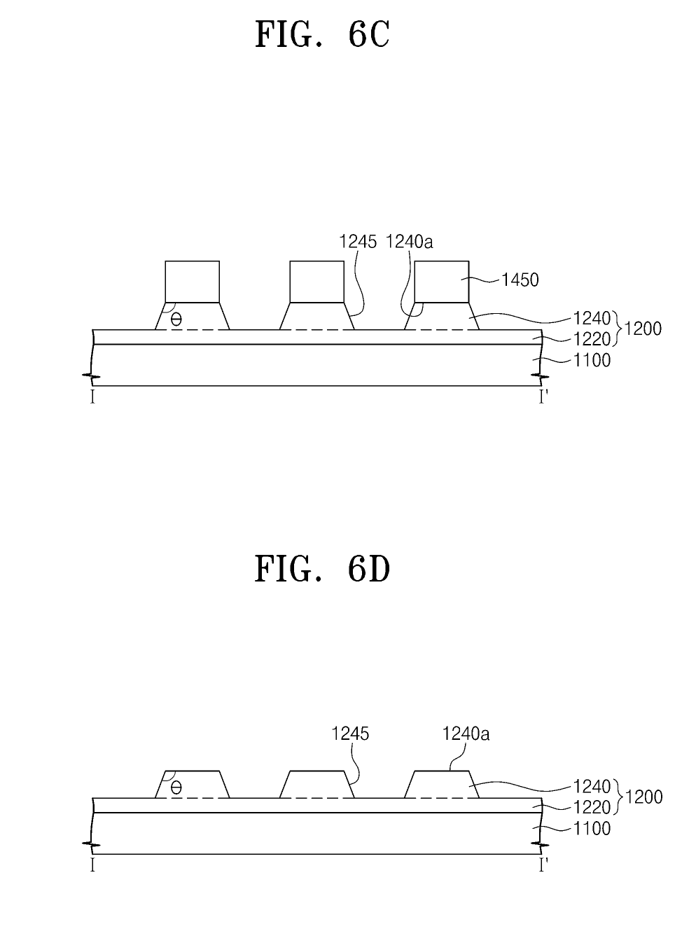

FIGS. 6A through 6D are sectional views illustrating a method of forming a pellicle membrane according to some example embodiments. In detail, FIGS. 6A through 6D illustrate sectional views corresponding to line I-I′ of FIG. 3.

Referring to FIGS. 3 and 6A, a silicon layer 1200 and a hard mask layer 1400 may be sequentially stacked on a substrate 1100. The substrate 1100 may include synthetic quartz, fused quartz, alkali-free glass, low alkali glass, soda lime glass, or nickel plate. The silicon layer 1200 may be formed of or include at least one of silicon (Si), silicon dioxide (SiO₂), silicon nitride (Si₃N₄), or silicon compounds containing at least one of zirconium (Zr), molybdenum (Mo), and ruthenium (Ru). The hard mask layer 1400 may be formed of or include at least one of silicon dioxide (SiO₂), silicon nitride (Si₃N₄), gold (Au), chromium (Cr), or silver (Ag). The hard mask layer 1400 may be formed by, for example, a chemical vapor deposition (CVD) or a plasma-enhanced CVD (PECVD). A photoresist 1500 may be formed on the hard mask layer 1400. The photoresist 1500 may be formed to have patterns, each of which is shaped like an island or a bar. The patterns may be regularly arranged along the first and second directions D1 and D2.

Referring to FIGS. 3 and 6B, the hard mask layer 1400 may be patterned using the photoresist 1500, and thus, a hard mask pattern 1450 may be formed on the silicon layer 1200. The hard mask pattern 1450 may be formed to expose a portion of the silicon layer 1200. When viewed in a plan view, the hard mask pattern 1450 may be shaped like an island or a bar.

Referring to FIGS. 3 and 6C, a wet etching process using the hard mask pattern 1450 may be performed on the silicon layer 1200 to form the silicon patterns 1240. Each of the silicon patterns 1240 may be formed to have a convex shape. The wet etching process may be performed using etching solution containing at least one of ethylenediamine pyrocatechol (EDP), potassium hydroxide (KOH), isopropyl alcohol (IPA), or tetramethylammonium hydroxide (TMAH). For example, in the case where EDP is used as the etching solution, the hard mask pattern 1450 may include at least one of silicon dioxide (SiO₂), silicon nitride (Si₃N₄), gold (Au), chromium (Cr) or silver (Ag). In the case where KOH, IPA, or TMAH is used as the etching solution, the hard mask pattern 1450 may include at least one of silicon dioxide (SiO₂) or silicon nitride (Si₃N₄). For a crystalline silicon layer, the number of Si—Si bonds per a unit area is greater on a (111) plane than (110) and (100) planes, and thus, the (111) plane exhibits a slower etch rate than those of the (110) and (100) planes in the wet etching process. As a result, an angle (θ) between the top surface 1240a (i.e., (100) plane) and the side surface 1245 (i.e., (111) plane) of the silicon pattern 1240 may be an obtuse angle. In certain cases, depending on etching conditions in the wet etching process or thicknesses of the hard mask layer 1400 and the photoresist 1500, the side surface 1245 of the silicon pattern 1240 may be rounded. For example, if the hard mask layer 1400 and the photoresist 1500 are thin, the hard mask layer 1400 and the photoresist 1500 may be wholly removed during the wet etching process, and in this case, each of the silicon patterns 1240 may have a triangular section.

Referring to FIGS. 3 and 6D, a hard mask pattern 1450 may be removed. The silicon patterns 1240 may be arranged at a uniform interval. Each of the silicon patterns 1240 may have a vertical section shaped like a trapezoid, a triangle, or a semi-circle.

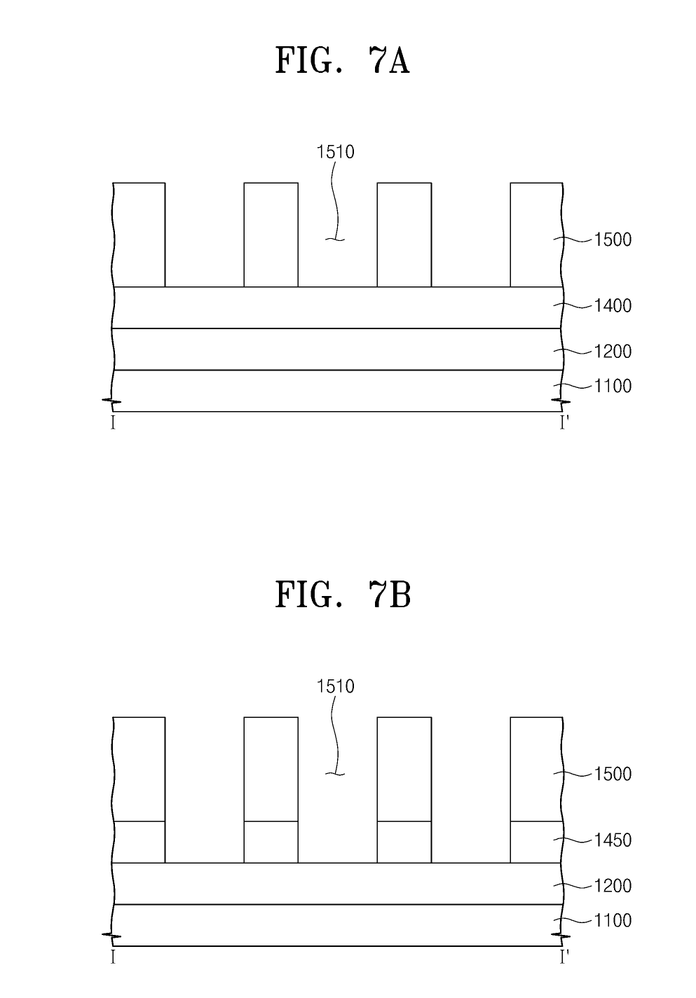

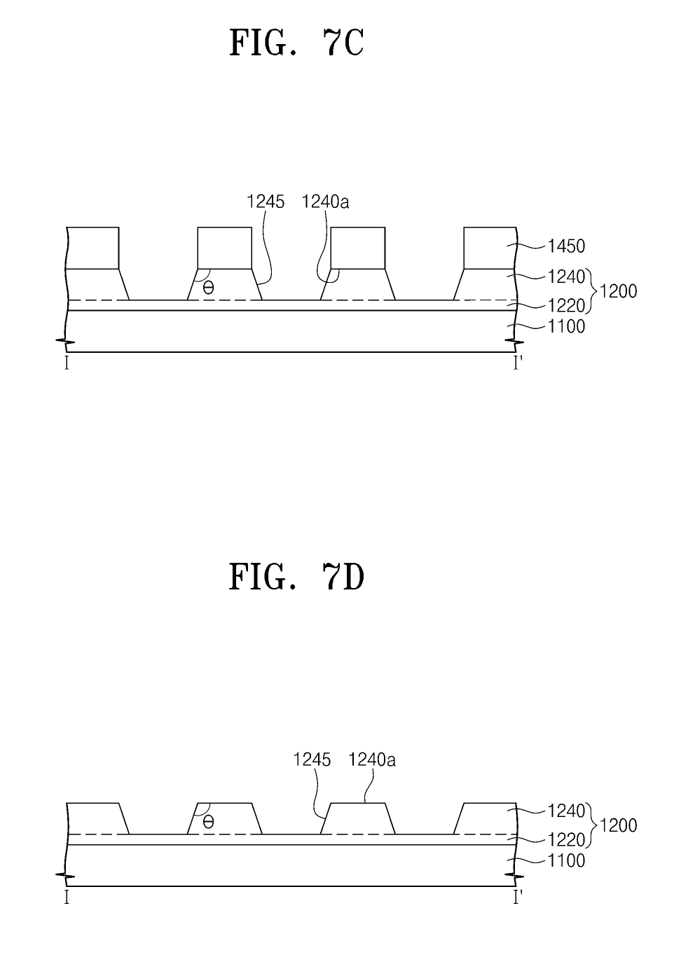

FIGS. 7A through 7D are sectional views illustrating a method of forming a pellicle membrane according to some example embodiments. In detail, FIGS. 7A through 7D illustrate sectional views corresponding to line I-I′ of FIG. 3. For concise description, a previously described element may be identified by a similar or identical reference number without repeating an overlapping description thereof.

Referring to FIGS. 3 and 7A, the silicon layer 1200 and the hard mask layer 1400 may be sequentially stacked on the substrate 1100. The substrate 1100 may include synthetic quartz, fused quartz, alkali-free glass, low alkali glass, soda lime glass, or nickel plate. The silicon layer 1200 may include at least one of silicon (Si), silicon dioxide (SiO₂), silicon nitride (Si₃N₄), and/or silicon compounds containing at least one of zirconium (Zr), molybdenum (Mo), and ruthenium (Ru). The hard mask layer 1400 may be formed of or include at least one of silicon dioxide (SiO₂), silicon nitride (Si₃N₄), gold (Au), chromium (Cr), and/or silver (Ag).

In some example embodiments, the hard mask layer 1400 may be formed by a chemical vapor deposition (CVD) or a plasma-enhanced CVD (PECVD). The photoresist 1500 may be formed on the hard mask layer 1400. The photoresist 1500 may be formed to define openings 1510 exposing the hard mask layer 1400. The openings 1510 may be regularly arranged along the first and second directions D1 and D2.

Referring to FIGS. 3 and 7B, the hard mask layer 1400 may be patterned using the photoresist 1500 to form the hard mask pattern 1450. The hard mask pattern 1450 may be formed to expose a portion of the silicon layer 1200.

Referring to FIGS. 3 and 7C, the silicon patterns 1240 may be formed using, for example, a wet etching process, as described with reference to FIG. 6C. Each of the silicon patterns 1240 may have a concave shape.

Referring to FIGS. 3 and 7D, the hard mask pattern 1450 may be removed. The silicon patterns 1240 may be arranged at a uniform interval. Each of the silicon patterns 1240 may have a vertical section shaped like a trapezoid, a triangle, or a semi-circle. In certain cases, depending on etching conditions in the wet etching process or thicknesses of the hard mask layer 1400 and the photoresist 1500, the side surface 1245 of the silicon pattern 1240 may be rounded.

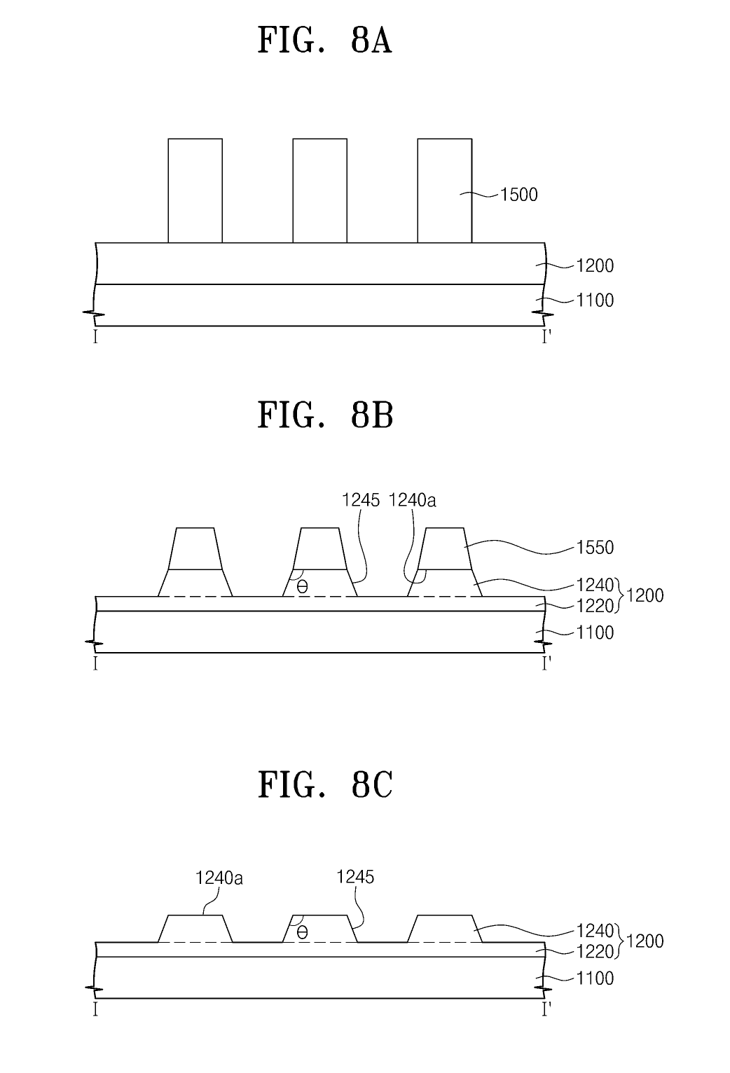

FIGS. 8A through 8C are sectional views illustrating a method of forming a pellicle membrane according to some example embodiments. In detail, FIGS. 8A through 8C illustrate sectional views corresponding to line I-I′ of FIG. 3.

Referring to FIGS. 3 and 8A, the silicon layer 1200 may be formed on the substrate 1100. The substrate 1100 may include synthetic quartz, fused quartz, alkali-free glass, low alkali glass, soda lime glass, or nickel plate. The silicon layer 1200 may include at least one of silicon (Si), silicon dioxide (SiO₂), silicon nitride (Si₃N₄), and/or silicon compounds containing at least one of zirconium (Zr), molybdenum (Mo), and ruthenium (Ru). The first resist pattern 1500 may be formed on the silicon layer 1200. When viewed in a plan view, the first resist pattern 1500 may be shaped like an island or a bar.

Referring to FIGS. 3 and 8B, a dry etching process may be performed using the first resist pattern 1500. In the case where the dry etching process is performed on the silicon layer 1200 exposed by the first resist pattern 1500, the first resist pattern 1500 may be partially etched to form a second resist pattern 1550. The second resist pattern 1550 may be formed to have a width and a thickness, which are smaller than those of the first resist pattern 1500. The dry etching process may be performed using etching gas containing fluorine (e.g., F⁻). In the dry etching process, a shape of the silicon pattern 1240 may be variously formed by controlling ratios in etch rate and thickness between the first resist pattern 1500 and the silicon layer 1200. Each of the silicon patterns 1240 may have a vertical section shaped like a trapezoid, a triangle, or a semi-circle. As an example, if a difference in etch rate between the first resist pattern 1500 and the silicon layer 1200 is high and the first resist pattern 1500 is thick, the silicon patterns 1240 may be formed to have a trapezoidal shape. By contrast, if a difference in etch rate between the first resist pattern 1500 and the silicon layer 1200 is small and the first resist pattern 1500 is thin, the silicon patterns 1240 may be formed to have a triangular or semi-circular shape.

Referring to FIGS. 3 and 8C, the second resist pattern 1550 may be removed. Each of the silicon patterns 1240 may be formed to have a convex shape. An angle (θ) between the top surface 1240a (i.e., (100) plane) and the side surface 1245 of the silicon pattern 1240 may be an obtuse angle.

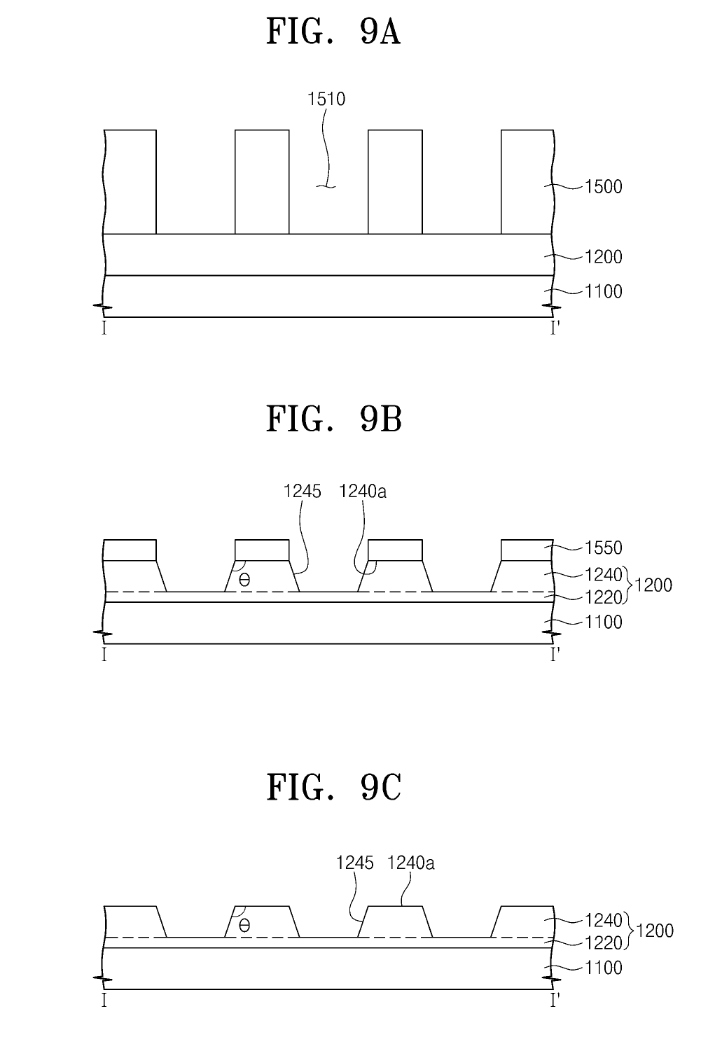

FIGS. 9A through 9C are sectional views illustrating a method of forming a pellicle membrane according to some example embodiments. In detail, FIGS. 9A through 9C illustrate sectional views corresponding to line I-I′ of FIG. 3.

Referring to FIGS. 3 and 9A, the silicon layer 1200 may be formed on the substrate 1100. The substrate 1100 may include synthetic quartz, fused quartz, alkali-free glass, low alkali glass, soda lime glass, or nickel plate. The silicon layer 1200 may include at least one of silicon (Si), silicon dioxide (SiO₂), silicon nitride (Si₃N₄), and/or silicon compounds containing at least one of zirconium (Zr), molybdenum (Mo), and ruthenium (Ru). The first resist pattern 1500 may be formed on the silicon layer 1200. The first resist pattern 1500 may be formed to define the openings 1510 exposing the silicon layer 1200. The openings 1510 may be regularly arranged along the first and second directions D1 and D2.

Referring to FIGS. 3 and 9B, a dry etching process may be performed using the first resist pattern 1500. When the dry etching process is performed on the silicon layer 1200 exposed by the first resist pattern 1500, the first resist pattern 1500 may be partially etched to form the second resist pattern 1550. Accordingly, the second resist pattern 1550 may be formed to have a width and a thickness, which are smaller than those of the first resist pattern 1500. During the dry etching process, a shape of the silicon pattern 1240 may be variously formed by controlling ratios in etch rate and thickness between the first resist pattern 1500 and the silicon layer 1200. Each of the silicon patterns 1240 may have a vertical section shaped like a trapezoid, a triangle, or a semi-circle.

Referring to FIGS. 3 and 9C, the second resist pattern 1550 may be removed. Each of the silicon patterns 1240 may have a concave shape.

Although not illustrated in the drawings, the pellicle membrane 1000 may be detached from the substrate 1100 and may be attached to the mask 230 of FIG. 2. The pellicle membrane 1000 may protect the mask 230 against pollutants (e.g., particles).

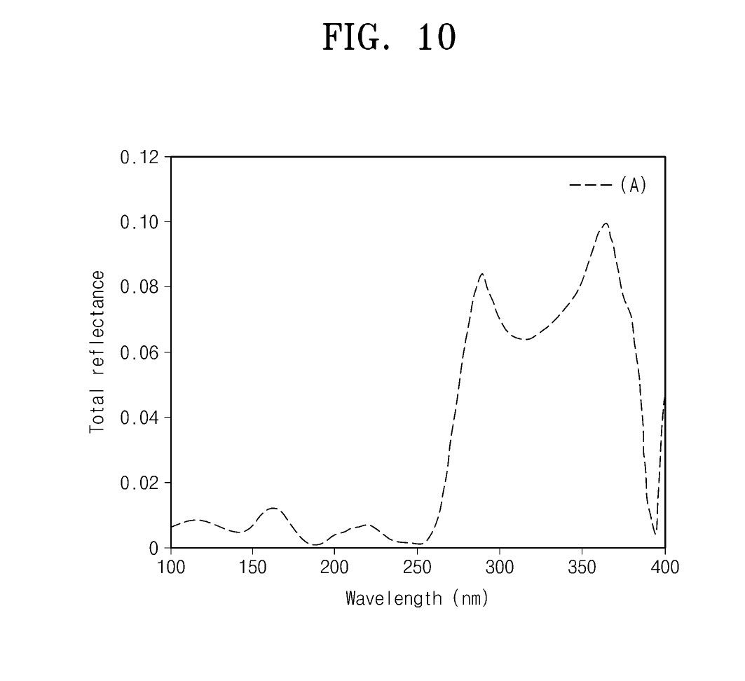

FIG. 10 is a graph showing reflectance characteristics of a pellicle membrane according to some example embodiments. Referring to FIG. 10, a pellicle membrane according to some example embodiments exhibited reflectance of 10% or less, when light of 100 nm to 400 nm is incident thereto. In particular, the pellicle membrane had reflectance of 1% or less, for light of 100 nm to 250 nm. FIG. 10 shows that by using the pellicle membrane according to some example embodiments, it is possible to reduce reflection of UV light. Thus, the usage of the pellicle membrane according to some example embodiments makes it possible to reduce a failure in an EUV exposure process.

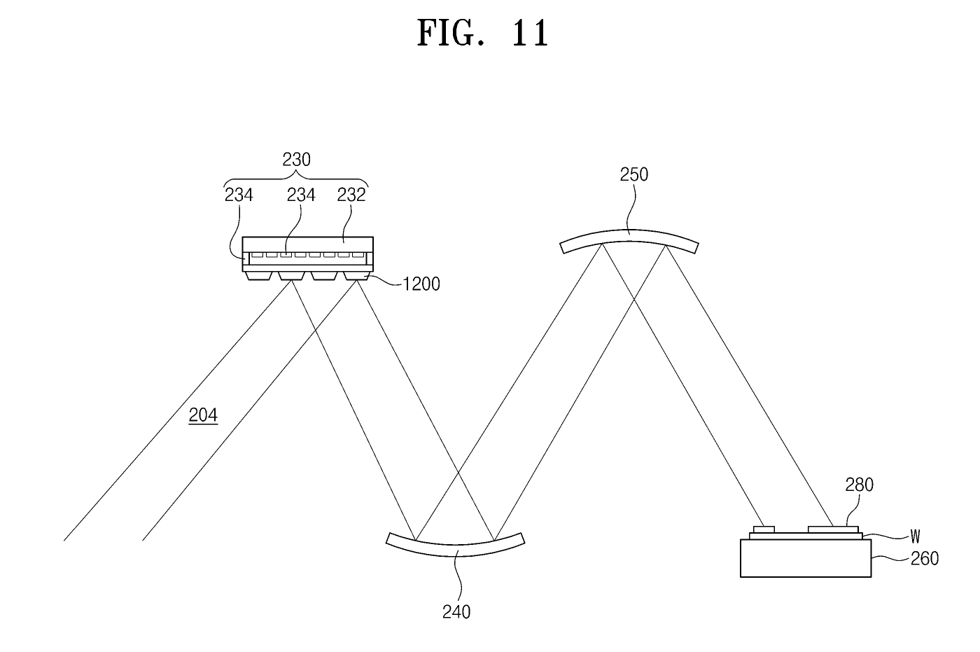

FIG. 11 is a diagram illustrating a lithography process of exposing a substrate using a mask. For concise description, an element previously described with reference to FIG. 2 may be identified by a similar or identical reference number without repeating an overlapping description thereof.

Referring to FIG. 11, a photosensitive film may be coated on the substrate W provided with an etch-target layer (not shown). An exposure process may be performed using the mask 230 according to some example embodiments. Here, the EUV beam 204 may be incident into the mask 230 in a direction at an angle to a top surface of the mask 230 and thus, a reflected beam may also be propagated in a direction at an angle to the top surface of the mask 230. The mask 230 may be configured to scatter light of 100 nm to 400 nm and reflect extreme ultraviolet (EUV) light of about 13.5 nm. Shapes and disposition of the mask patterns 234 may be transferred onto the substrate W. The mask patterns 234 may reflect the EUV beam 204, and the fraction of the EUV beam 204 reflected by the mask patterns 234 may be used for an exposure process to be performed on the substrate W. A developing process may be performed on a photosensitive film, on which the exposure process has been performed, and consequently, photoresist patterns 280 may be formed on the substrate W. The photoresist patterns 280 may be used as an etch mask in an etching process of etching the etch-target layer (not shown). The etch-target layer (not shown) may be etched to form patterns on the substrate W.

According to some example embodiments, it is possible to reduce an amount of ultraviolet light to be reflected from silicon patterns of a pellicle membrane.

According to some example embodiments, it is possible to easily remove particles attached on a pellicle membrane.

While some example embodiments have been particularly shown and described, it will be understood by one of ordinary skill in the art that variations in form and detail may be made therein without departing from the spirit and scope of the attached claims.

What is claimed is:

1. A method of manufacturing a pellicle membrane, comprising:
forming a silicon layer on a substrate;
forming a mask pattern on the silicon layer; and
performing a wet etching process on the silicon layer exposed by the mask pattern to form silicon patterns with an uneven structure, such that a contact area between the silicon patterns and the substrate is larger than that between the silicon patterns and the mask pattern, and
each of the silicon patterns is formed in such a way that a side surface thereof has an ascending slope in a vertical direction oriented from the substrate toward the mask pattern.

2. The method of claim 1, wherein the mask pattern comprises:
a hard mask pattern; and
a resist pattern provided on the hard mask pattern.

3. The method of claim 2, wherein the wet etching process is performed using an etching solution containing at least one of ethylenediamine pyrocatechol (EDP), potassium hydroxide (KOH), isopropyl alcohol (IPA), and tetramethylammonium hydroxide (TMAH).

4. The method of claim 3, wherein if the etching solution is EDP, the hard mask pattern includes at least one of silicon dioxide (SiO₂), silicon nitride (Si₃N₄), gold (Au), chromium (Cr), and silver (Ag).

5. The method of claim 3, wherein if the etching solution is KOH, IPA, or TMAH, the hard mask pattern includes one of silicon dioxide (SiO₂) and silicon nitride (Si₃N₄).

6. The method of claim 1, wherein the forming a mask pattern forms the mask pattern having openings exposing the silicon layer, the openings arranged in a regular manner, along a first direction and a second direction crossing the first direction.

7. The method of claim 1, wherein the forming a mask pattern forms the mask pattern to have an island shape.

8. The method of claim 1, wherein the performing a wet etching process forms the silicon patterns arranged at a uniform interval.

9. The method of claim 1, wherein performing a wet etching process forms the silicon pattern to have top and side surfaces meeting at an obtuse angle.

10. The method of claim 1, further comprising:
removing the mask pattern, after the wet etching process.

11. A method of manufacturing a pellicle membrane, comprising:
forming a silicon layer on a substrate;
forming a first resist pattern on the silicon layer; and
patterning the first resist pattern and the silicon layer exposed by the first resist pattern using a dry etching process to form a second resist pattern and silicon patterns, such that the second resist pattern has a width and a thickness smaller than those of the first resist pattern, the silicon patterns have an uneven structure on the silicon layer, and
a contact area between the silicon patterns and the substrate is larger than that between the silicon patterns and the second resist pattern.

12. The method of claim 11, wherein the silicon pattern is formed to have top and side surfaces meeting at an obtuse angle.

13. The method of claim 11, wherein the dry etching process is performed using an etching gas containing fluorine.

14. The method of claim 11, wherein the silicon patterns are formed at a uniform interval on the silicon layer and each of the silicon patterns is shaped like a bar.

15. The method of claim 11, further comprising removing the second resist pattern.

16. The method of claim 1, wherein the side surface is a crystal plane of (111).

17. A method of manufacturing a pellicle membrane, the method comprising:
forming a silicon layer on a substrate; and
forming silicon patterns on the silicon layer, each of the silicon patterns formed such that a side surface thereof has an ascending slope in a vertical direction oriented from the substrate,
wherein a distance between the silicon patterns is similar to the thickness of the silicon layer.

18. The method of claim 17, wherein the forming a silicon layer on a substrate comprises: sequentially stacking a silicon layer and a hard mask layer on a substrate.

19. The method of claim 18, wherein the forming silicon patterns comprises:
forming a photoresist on the hard mask layer so as to define openings exposing the hard mask layer, the openings being regularly arranged in a first direction and a second direction;
patterning the hard mask layer to form a hard mask pattern; and
forming silicon patterns on the silicon layer using the hard mask pattern as a mask, the silicon patterns arranged at substantially uniform intervals, a contact area between the silicon patterns and the substrate being larger than that between the silicon patterns and the hard mask pattern.

20. The method of claim 19, wherein the silicon patterns have a concave shape and a side surface of the silicon patterns is rounded.
